(19) United States
(12) Patent Application Publication
(10) Pub. No.: US 2025/0061925 A1
(43) Pub. Date: Feb. 20, 2025

(54) DIRECT DECISION FEEDBACK EQUALIZATION SINGLE-ENDED RECEIVER

(71) Applicant: Micron Technology, Inc., Boise, ID (US)

(72) Inventors: Sai Vidya Manohar Raju Kasturi, Hyderabad (IN); Rahul Krishna Velitheri, Hyderabad (IN)

(21) Appl. No.: 18/804,865

(22) Filed: Aug. 14, 2024

Related U.S. Application Data
(60) Provisional application No. 63/533,230, filed on Aug. 17, 2023.

(51) Int. Cl. G11C 5/14; H04L 25/03

(52) U.S. Cl. CPC G11C 5/147; G11C 5/148; H04L 25/03267

(57) ABSTRACT

A system including a memory sub-system controller to transmit a data signal via a communication channel. The system includes a receiver to receive the data signal from the memory sub-system controller via an interface, the receiver comprising a decision feedback equalizer (DFE) sub-system. The DFE sub-system includes a first data detector circuit including a first tap circuit, where the first data detector circuit generates, using a first reference voltage, a first subset of detected values corresponding to the data signal. The DFE sub-system includes a second data detector circuit including a second tap circuit, where the second data detector circuit generates a second subset of detected bit values corresponding to the data signal using a second reference voltage.

### CROSS-REFERENCE TO RELATED APPLICATION

This application claims the benefit of U.S. Provisional Application No. 63/533,230, filed Aug. 17, 2023, which is hereby incorporated herein by reference in its entirety.

### TECHNICAL FIELD

Embodiments of the disclosure relate generally to data communications, and more specifically, relate to a high speed interface and data communication path having direct decision feedback equalization for data transmissions associated with a memory device in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, in accordance with one or more embodiments of the present disclosure.

FIG. 1B is a block diagram of a memory device in communication with a memory sub-system controller of a memory sub-system, in accordance with one or more embodiments of the present disclosure.

FIG. 2A-2D are schematics of portions of an array of memory cells as could be used in a memory of the type described with reference to FIG. 1B, in accordance with one or more embodiments of the present disclosure.

FIG. 3 is a block schematic of a portion of an array of memory cells as could be used in a memory of the type described with reference to FIG. 1B, in accordance with one or more embodiments of the present disclosure.

FIG. 4 illustrates an example memory sub-system including a transmitter to transmit data via a communication channel to a receiver including a direct decision feedback equalizer to generate digital samples corresponding to received data, in accordance with one or more embodiments of the present disclosure.

FIG. 5 illustrates an example direct decision feedback equalizer, in accordance with one or more embodiments of the present disclosure.

FIG. 6 illustrates an example one-tap data detector of a direct decision feedback equalizer, in accordance with one or more embodiments of the present disclosure.

FIG. 7 illustrates an example multi-tap data detector of a direct decision feedback equalizer, in accordance with one or more embodiments of the present disclosure.

FIG. 8 is a flow diagram of an example method of generating a set of detected bit values corresponding to an incoming data signal received from transmitter via a communication channel, in accordance with one or more embodiments of the present disclosure.

FIG. 9 is a block diagram of an example computer system in which embodiments of the present disclosure may operate.

### DETAILED DESCRIPTION

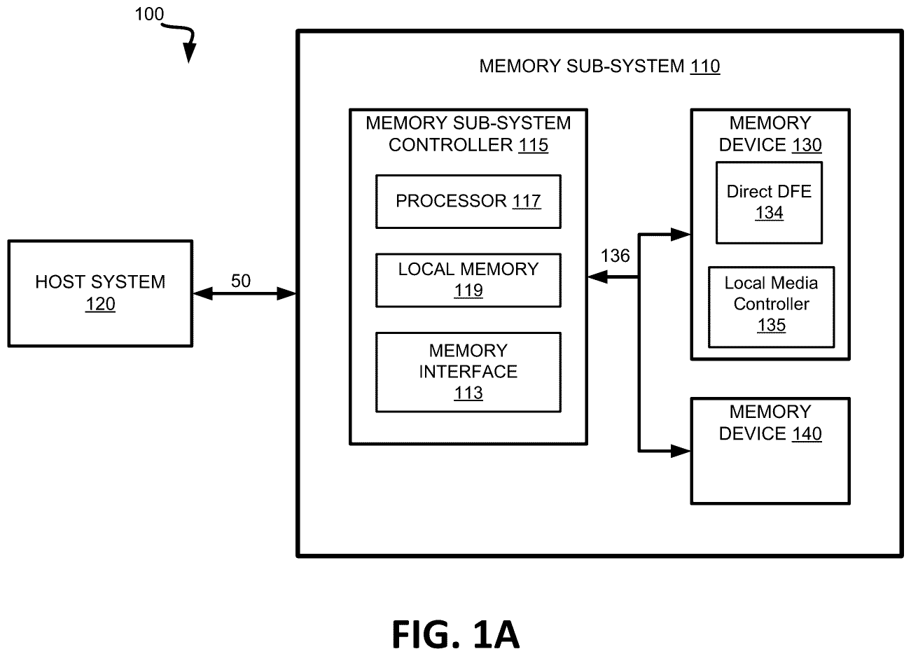

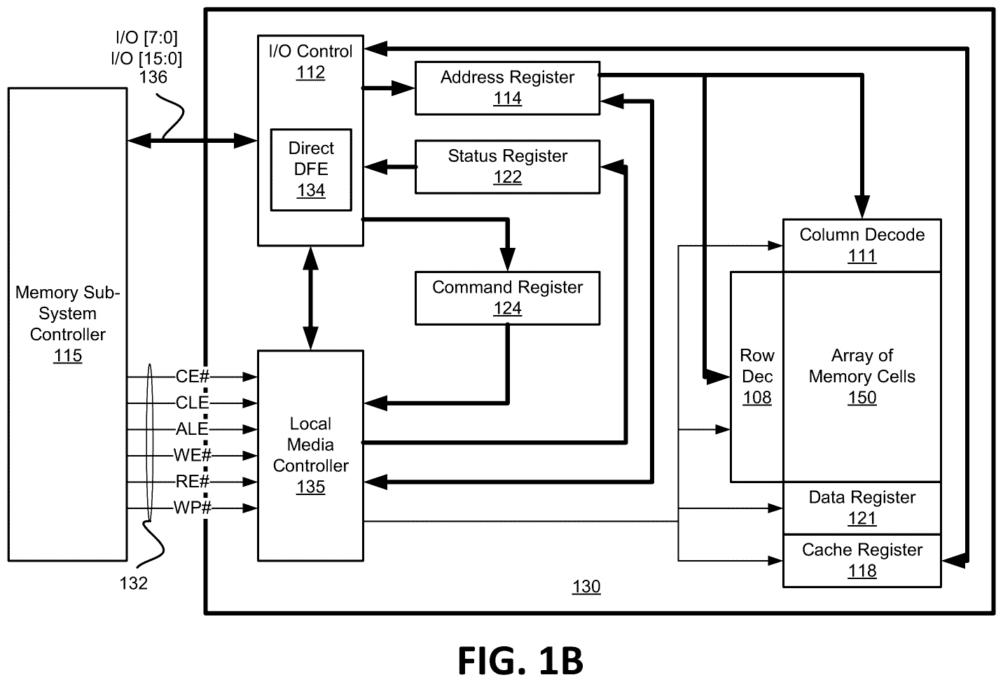

Aspects of the present disclosure are directed to enhanced speed capability of data transmissions in a data path using direct mode decision feedback equalization of data associated with a memory device in a memory sub-system. A memory sub-system can be a storage device, a memory module, or a combination of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a NOT-and (NAND) memory device. Other examples of non-volatile memory devices are described below in conjunction with FIG. 1A. A non-volatile memory device is a package of one or more dice. Each die can include two or more planes. For some types of non-volatile memory devices (e.g., NAND devices), each plane includes of a set of physical blocks. In some implementations, each block can include multiple sub-blocks. Each plane carries a matrix of memory cells formed on a silicon wafer and joined by conductors referred to as wordlines (WLs) and bitlines (BLs), such that a wordline joins multiple memory cells forming a row of the matrix of memory cells, while a bitline joins multiple memory cells forming a column of the matrix of memory cells.

Depending on the cell type, each memory cell can store one or more bits of binary information, and has various logic states that correlate to the number of bits being stored. The logic states can be represented by binary values, such as “0” and “1,” or combinations of such values, also referred to herein as logical bit values. A memory cell can be programmed (written to) by applying a certain voltage to the memory cell, which results in an electric charge being held by the memory cell, thus allowing modulation of the voltage distributions produced by the memory cell. A set of memory cells referred to as a memory page can be programmed together in a single operation, e.g., by selecting consecutive bitlines.

A memory device can be made up of bits arranged in a two-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including the different page types (e.g., LPs, UPs, XPs, and TPs).

To perform a programming operation initiated by a host system, the data to be programmed to the memory array of the memory device is transmitted via a communication channel or data path between a transmitter (e.g., a memory sub-system controller) and a receiver (e.g., a memory device) in a double data rate (DDR) memory sub-system. Several signal processing techniques can be applied to monitor and verify the accuracy of the high speed data that is transmitted to the memory device. For example, the transmitter and receiver can employ serializer/deserializer (SerDes) technology configured to execute techniques to mitigate high intersymbol interference (ISI) from highly dispersive and reflective channels, such as an equalization technique. Example equalization techniques include linear algorithms such as Zero-Forcing and Minimum Mean Square Estimation (MMSE) equalizers. In linear equalizers, each output sample is a simple linear combination (i.e., as determined by the equalizer taps) of the input samples. However, linear equalizers suffer from significant performance issues, including the generation of signal noise and the production of inaccurate sample estimations.

Accordingly, to address the drawbacks associated with linear equalization in a single-ended receive path, certain transmission systems employ Decision Feedback Equalization (DFE). Decision feedback equalization employs nonlinear equalization to equalize the channel using a feedback loop based on previously decided symbols, which can be used to remove ISI and other noise. The DFE provides nonlinear equalization which relies on decisions about the levels of previous symbols (e.g., high/low) to correct the current symbol estimate to allow the DFE to account for distortion in the current symbol that is caused by the previous symbols. Some DFE configurations use slicers to quantize a signal to a binary “1” or “0” based on the sampled value and a slicer threshold. These DFE architectures employ multiple data detectors or digital slicers to perform detection on the signal to recover the actual data that was transmitted. Each slicer is configured to produce detected data bits or symbols taken at time intervals (e.g., a data sample associated with time n). In one example, the data detector performs a slicing operation to convert a first analog value to a digital decision estimate or sample, thereby reflecting a filtered or equalized version of the equalized input signal. The data detector can include one or more latches which “slice” a voltage at a programmable threshold or an ADC, which produces a multi-bit output from which the data can be detected and used for purposes of the programming of the memory cells of the memory device.

According to certain approaches, two data detectors or slicers are employed to generate digital estimations of different samples of the incoming or transmitted signal. Each slicer takes a sample of the incoming signal (i.e., the transmitted signal) at a time interval (e.g., the first slicer takes a first sample at time T0, the second slicer takes a second sample at time T1, the first slicer takes a third sample at time T2, and so on) and compares it to a common static common reference voltage level to generate a digital estimation of the data sample. For example, the slicer can determine that the digital estimation is “1” if the incoming signal value is greater than the reference voltage level or “0” if the incoming signal value is less than the reference voltage level. According to these implementations, the two slicers share the same or common static reference voltage. The DFE can include one or more taps that are applied to normalized voltages based on a symbol slicer decision, where the tap values are used to correct for a portion of the tap symbol that distorts the current symbol. Each tap is associated with a weight or “tap coefficient” to adjust the slicer response to compensate for unknown factors and elements of the communication medium between the transmitter and the receiver.

In certain DFE architectures, the two slicers are employed in a half-rate scheme where each slicer is associated with its own offset. The offset can be due to differences in the transistors (e.g., differences due to manufacturing) arranged in the incoming signal path and the reference voltage path. To compensate for any offset between the incoming signal path and the reference voltage path, a source de-generation resistance scheme can be employed where offset correction circuits (e.g., a set of transistors) are arranged in the incoming signal path and the reference voltage path. However, implementing the dedicated offset correction circuitry in the respective paths results in a degradation of the speed of the signal. This loss in speed in caused by resistance associated with the offset correction circuits arranged in series with the incoming signal path.

Furthermore, these architectures use a single reference voltage (i.e., a common Vref) which provides a static voltage level for use by each of the slicers in generating the digital estimation of the received data signal. Since the resistances of the two offset correction circuitry are in series and the corresponding resistance is fixed, an overall switch resistance is non-linear if binary code resistances are used.

In some architectures, each slicer includes capacitive circuitry for use in enabling the tap functionality. For example, each slicer can include a first capacitive circuit arranged in the incoming signal path that stores a voltage (i.e., the capacitor voltage) that is used to control the slicer tap. The incoming signal is received by one or more transistors of the slicer and passed through the capacitive circuit where the capacitor voltage is added to boost the signal voltage amplitude to improve the detectability of the signal at high frequency rates and control the feedback tap. Similarly, a second capacitive circuit is arranged in the reference voltage path to boost the reference voltage prior to comparison with the boosted incoming signal voltage. However, introduction of the capacitive storage in the data path results in a degradation of the signal speed as data rates increase.

Furthermore, some DFE architectures include multi-tap slicers. In these approaches, each of the multiple taps of the slicer has corresponding capacitive circuits arranged in the main signal path. Accordingly, the multiple capacitive circuits in the main signal path that are used to control the operation of the respective taps of the multi-tap slicer disadvantageously reduces the data rate of the DFE.

Aspects of the present disclosure address the above and other deficiencies by implementing a direct decision feedback equalization mode approach to enhance the speed capability of data transmitted via a data path between a transmitter (e.g., a memory sub-system controller) and a single-ended receiver (e.g., a memory device). In an embodiment, the decision feedback equalization (also referred to as direct decision feedback equalization) is implemented using a direct decision feedback equalizer (i.e., a direct DFE that receives the incoming signal directly from the transmitter) that includes multiple data detectors (e.g., a first slicer and a second slicer) that are each associated with respective reference voltages. According to embodiments, the direct DFE interface processes single-ended signals received from the memory sub-system controller.

According to embodiments, the direct DFE includes a first slicer (slicer 1) associated with a first reference voltage (Vref1) and a second slicer (slicer 2) associated with a second reference voltage (Vref2). Advantageously, use of the multiple reference voltages enables the removal of dedicated offset compensation circuitry from the data path. According to embodiments, the use two different reference voltages for the two slicers enables high speed transmissions that are not degraded by having source degenerating resistance in the high speed data path. Advantageously, the two different reference voltages (i.e., Vref1 for the first slicer and Vref2 for the second slicer) are used to cancel the slicer offset, without the use of offset correction circuitry in the data path.

According to embodiments, each slicer includes a standalone voltage generator circuit to generate a voltage to control the feedback tap of the slicer (herein referred to as the “tap voltage”). Advantageously, the tap voltage is generated by the tap voltage generator to control the slicer tap in a branch that is parallel to the signal path, thereby enabling the removal of capacitive circuitry from the signal path. The use of the tap voltage generator in a parallel branch relative to the main or primary signal path provides for control of the tap functionality, without the need for separate capacitive circuitry in the signal path, which leads to an increase in the data rate processing of the direct DFE.

According to embodiments, the direct DFE can be used with slicers with multiple taps (e.g., tap 1, tap 2, tap 3, etc.). Advantageously, the multi-tap direct DFE can include tap voltage generators arranged parallel to the signal path for controlling the multiple taps, without the use of a capacitive circuit for each tap in the signal path.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110 via an interface 50 (e.g., a peripheral component interconnect (PCI) or Serial Advanced Technology Attachment (SATA) interface). As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory page buffers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory

Memory device 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 110 are provided to decode address signals. Address signals are received and decoded to access the array of memory cells 104. Memory device 130 also includes input/output (I/O) control circuitry 112 to manage input of commands, addresses and data to the memory device 130 as well as output of data and status information from the memory device 130. An address register (or address page buffer) 114 is in communication with I/O control circuitry 112 and row decode circuitry 108 and column decode circuitry 111 to latch the address signals prior to decoding. A command register (or command page buffer) 124 is in communication with I/O control circuitry 112 and local media controller 135 to latch incoming commands.

According to embodiments, the I/O control circuitry 112 includes a direct DFE 134 to receive incoming data associated with the memory device 130 (e.g., data for use in a programming operation associated with the memory device 130). The direct DFE 134 receives the incoming data (e.g., data transmitted by the memory sub-system controller 115) and generates digital estimates associated with samples of the transmitted data signal, according to embodiments of the present disclosure. As described in greater detail below, the direct DFE 134 includes two data detector circuits (i.e., two slicers) that each employ a respective reference voltage to generate the corresponding digital samples. According to embodiments, the direct DFE 134 uses a first reference voltage to control the first slicer and a second reference voltage to control the second slicer. Advantageously, the use of two difference reference voltages to control the two slicers cancels or corrects the offset between the slicers, without the need for additional offset correction circuitry within the signal path. The elimination of the need for the additional offset correction circuitry in view of the correction of the slicer offset due to the use of the two different reference voltages increases the data rate and frequency capability of the I/O control circuitry 112.

According to embodiments, each slicer of the direct DFE 134 includes a separate or standalone voltage generator circuit to generate a voltage to control the feedback tap of the slicer (herein referred to as the “tap voltage”). According to embodiments, the tap voltage generator generating the tap voltage that controls the slicer tap is arranged in a branch of the slicer circuitry that is parallel to the signal path. Accordingly, the slicer tap can be controlled by the tap voltage without the need for capacitive circuitry arranged in the signal path (i.e., in series with the incoming signal). Therefore, use of the voltage generator to provide the tap voltage in a parallel branch leads to an increase in the speed of the processing of the direct DFE, since capacitive elements are not used within the signal path. Providing the tap voltage with the tap voltage generator that is parallel to the signal path mimics the function performed by capacitive circuitry in prior DFE architectures.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 111 to control the row decode circuitry 108 and column decode circuitry 111 in response to the addresses. In one embodiment, local media controller 135 includes the direct DFE 134, which can implement the page mapping scheme including placement of first data associated with a first subset of page types (e.g., LPs and UPs) into a first subset of memory cells of a first subset of bitlines (e.g., even-numbered bitlines) and placement of second data associated with a second subset of page types (e.g., XPs and TPs) into a second subset of memory cells of a second subset of bitlines (e.g., odd-numbered bitlines) during a programming operation of a set of target memory cells of the one or more memory devices 130.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 121 for transfer to the array of memory cells 104; then new data may be latched in the cache register 118 from the I/O control circuitry 112. During a read operation, data may be passed from the cache register 118 to the I/O control circuitry 112 for output to the memory sub-system controller 115; then new data may be passed from the data register 121 to the cache register 118. The cache register 118 and/or the data register 121 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status register (or status page buffer) 122 may be in communication with I/O control circuitry 112 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130.

According to embodiments, memory device 130 receives command signals (which represent commands), address signals (which represent addresses), and data signals (which represent data) from the memory sub-system controller 115 over a multiplexed input/output (I/O) interface 136 and outputs data to the memory sub-system controller 115 over I/O interface 136. In an embodiment, the memory sub-system controller 115 operates as a transmitter to transmit one or more data signals via a communication channel (i.e., I/O interface 136) to the memory device 130 (i.e., a receiver) that includes a direct DFE to receive and process the one or more data signals.

For example, the commands may be received over input/output (I/O) pins [7:0] of I/O interface 136 at I/O control circuitry 112 and may then be written into command page buffer 124. The addresses may be received over input/output (I/O) pins [7:0] of I/O interface 136 at I/O control circuitry 112 and may then be written into address page buffer 114. The data may be received over input/output (I/O) pins [7:0] for an 8-bit device or input/output (I/O) pins [15:0] for a 16-bit device at I/O control circuitry 112 and then may be written into cache register 118. The data may be subsequently written into data register 121 for programming the array of memory cells 104.

In an embodiment, cache register 118 may be omitted, and the data may be written directly into data register 121. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

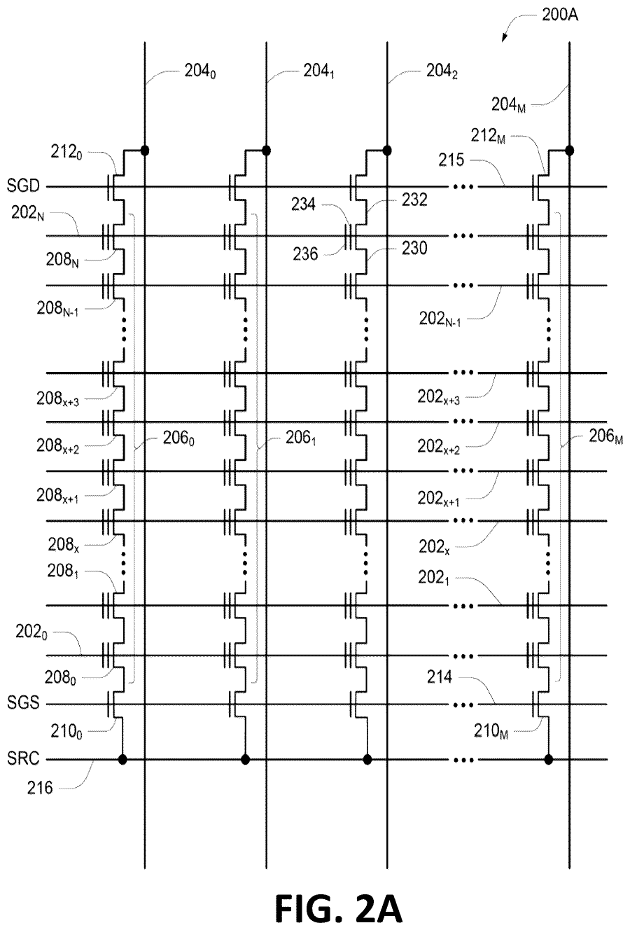

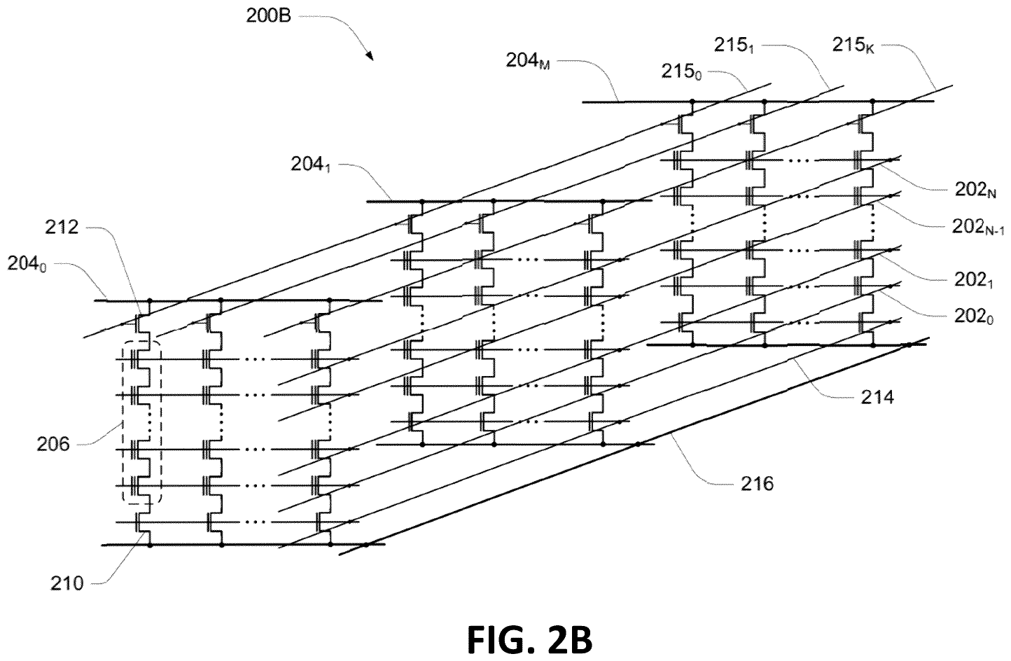

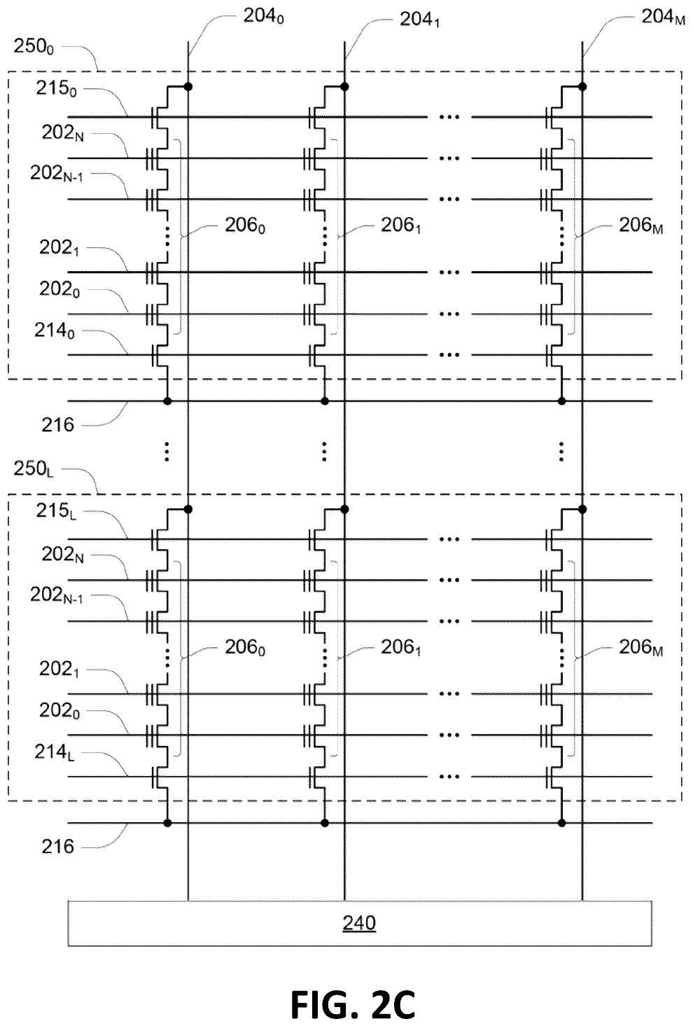

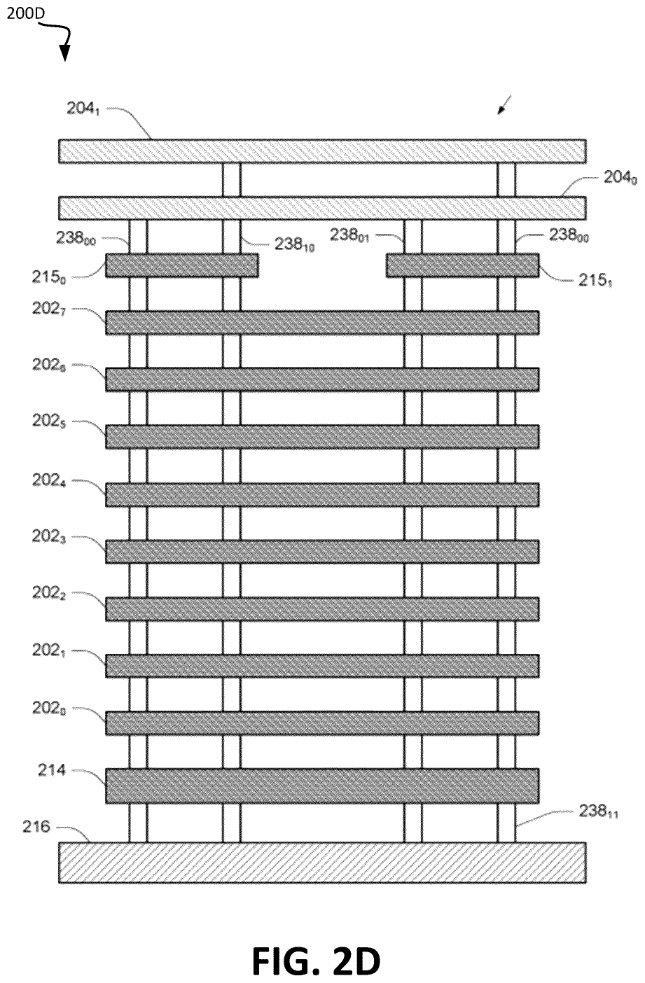

FIGS. 2A-2C are diagrams of portions of an example array of memory cells included in a memory device, in accordance with some embodiments of the present disclosure. For example, FIG. 2A is a schematic of a portion of an array of memory cells 200A as could be used in a memory device (e.g., as a portion of array of memory cells 104). Memory array 200A includes access lines, such as wordlines 202₀ to 202_{N}, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows each corresponding to a respective wordline 202 and columns each corresponding to a respective bitline 204. Rows of memory cells 208 can be divided into one or more groups of physical pages of memory cells 208, and physical pages of memory cells 208 can include every other memory cell 208 commonly connected to a given wordline 202. For example, memory cells 208 commonly connected to wordline 202_{N} and selectively connected to even bitlines 204 (e.g., bitlines 204₀, 204₂, 204₄, etc.) may be one physical page of memory cells 208 (e.g., even memory cells) while memory cells 208 commonly connected to wordline 202_{N} and selectively connected to odd bitlines 204 (e.g., bitlines 204₁, 204₃, 204₅, etc.) may be another physical page of memory cells 208 (e.g., odd memory cells). Although bitlines 204₃-204₅ are not explicitly depicted in FIG. 2A, it is apparent from the figure that the bitlines 204 of the array of memory cells 200A may be numbered consecutively from bitline 204₀ to bitline 204_{M}. Other groupings of memory cells 208 commonly connected to a given wordline 202 may also define a physical page of memory cells 208. For certain memory devices, all memory cells commonly connected to a given wordline might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells may include those memory cells that are configured to be erased together, such as all memory cells connected to wordlines 202₀-202_{N} (e.g., all strings 206 sharing common wordlines 202). Unless expressly distinguished, a reference to a page of memory cells herein refers to the memory cells of a logical page of memory cells.

Each column can include a string of series-connected memory cells (e.g., non-volatile memory cells), such as one of strings 206₀ to 206_{M}. Each string 206 can be connected (e.g., selectively connected) to a source line 216 (SRC) and can include memory cells 208₀ to 208_{N}. The memory cells 208 of each string 206 can be connected in series between a select gate 210, such as one of the select gates 210₀ to 210_{M}, and a select gate 212, such as one of the select gates 212₀ to 212_{M}. In some embodiments, the select gates 210₀ to 210_{M} are source-side select gates (SGS) and the select gates 212₀ to 212_{M} are drain-side select gates. Select gates 210₀ to 210_{M} can be connected to a select line 214 (e.g., source-side select line) and select gates 212₀ to 212_{M} can be connected to a select line 215 (e.g., drain-side select line). The select gates 210 and 212 might represent a plurality of select gates connected in series, with each select gate in series configured to receive a same or independent control signal. A source of each select gate 210 can be connected to SRC 216, and a drain of each select gate 210 can be connected to a memory cell 208₀ of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208_{N} of the corresponding string 206. Therefore, each select gate 212 might be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The three-dimensional memory array 200B may incorporate vertical structures which may include semiconductor pillars where a portion of a pillar may act as a channel region of the memory cells of strings 206. The strings 206 may be each selectively connected to a bit line 204₀-204_{M} by a select gate 212 and to the SRC 216 by a select gate 210. Multiple strings 206 can be selectively connected to the same bitline 204. Subsets of strings 206 can be connected to their respective bitlines 204 by biasing the select lines 215₀-215_{L} to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly connected to each other by a particular wordline 202 may collectively be referred to as tiers.

FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation, sometimes referred to as erase blocks. Each block of memory cells 250 can represent those NAND strings 206 commonly associated with a single select line 215, e.g., select line 215₀. The source 216 for the block of memory cells 250o can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bitlines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bitlines 204.

FIG. 2D is a diagram of a portion of an array of memory cells 200D (e.g., a portion of the array of memory cells 104). Channel regions (e.g., semiconductor pillars) 238₀₀ and 238₀₁ represent the channel regions of different strings of series-connected memory cells (e.g., strings 206 of FIGS. 2A-2C) selectively connected to the bitline 204₀. Similarly, channel regions 238₁₀ and 238₁₁ represent the channel regions of different strings of series-connected memory cells (e.g., NAND strings 206 of FIGS. 2A-2C) selectively connected to the bitline 204₁. A memory cell (not depicted in FIG. 2D) may be formed at each intersection of a wordline 202 and a channel region 238, and the memory cells corresponding to a single channel region 238 may collectively form a string of series-connected memory cells (e.g., a string 206 of FIGS. 2A-2C). Additional features might be common in such structures, such as dummy wordlines, segmented channel regions with interposed conductive regions, etc.

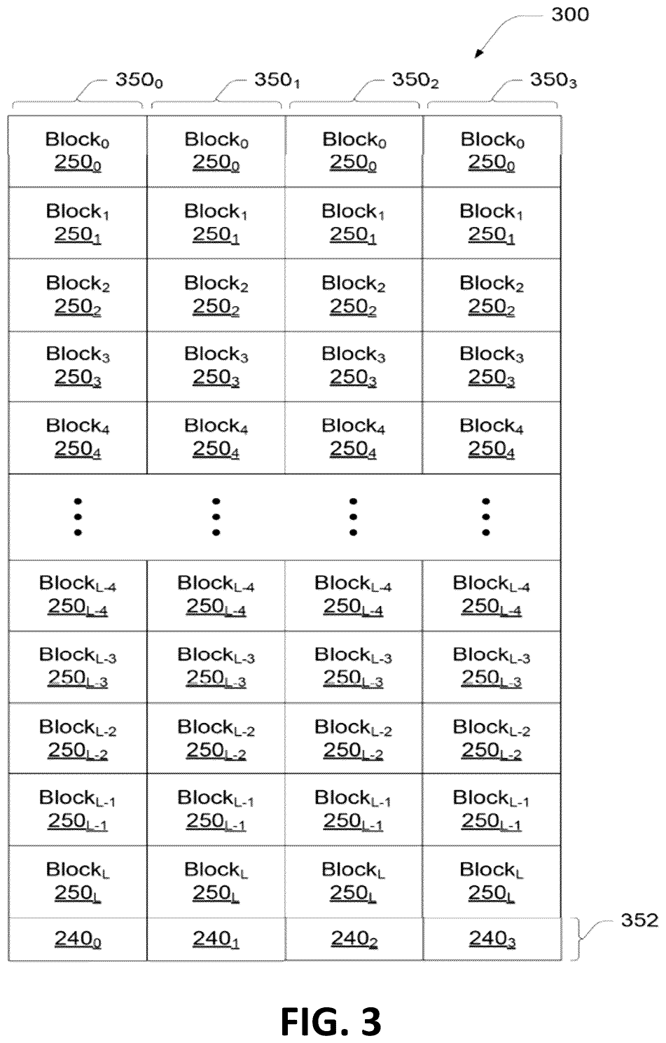

FIG. 3 is a block schematic of an example portion of an array of memory cells 300 as could be used in a memory of the type described with reference to FIG. 1B. The array of memory cells 300 is depicted as having four memory planes 350 (e.g., memory planes 350₀-350₃), each in communication with a respective buffer portion 240, which can collectively form a page buffer 352. While four memory planes 350 are depicted, other numbers of memory planes 350 can be commonly in communication with a page buffer 352. Each memory plane 350 is depicted to include L+1 blocks of memory cells 250 (e.g., blocks of memory cells 250₀-250_{L}).

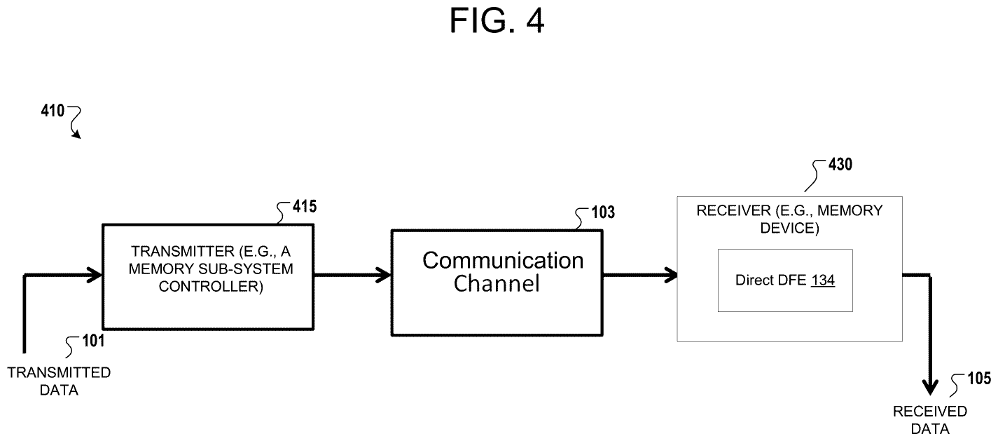

FIG. 4 illustrates an example memory sub-system 410 including a transmitter 415 (e.g., a memory sub-system controller 115 of FIGS. 1A and 1B) to transmit data 101 via a communication channel 103 to a receiver 430 (e.g., memory device 130 of FIGS. 1A and 1B) including a direct decision feedback equalizer 134 to generate digital samples corresponding to received data 105, according to embodiments of the present disclosure. In an embodiment, the transmitted data 101 may be provided to the transmitter 415 by a host system (e.g., host system 120 of FIG. 1A) and relate to a memory access operation (e.g., a programming operation) to be performed with respect to a memory device (e.g., memory device 130 of FIGS. 1A and 1B). According to embodiments, the transmitter 415 can include memory sub-system controller communicatively coupled to a memory device via a communication channel 103 can include any suitable communication medium, including but not limited to a trace, a cable, a circuit board, etc.

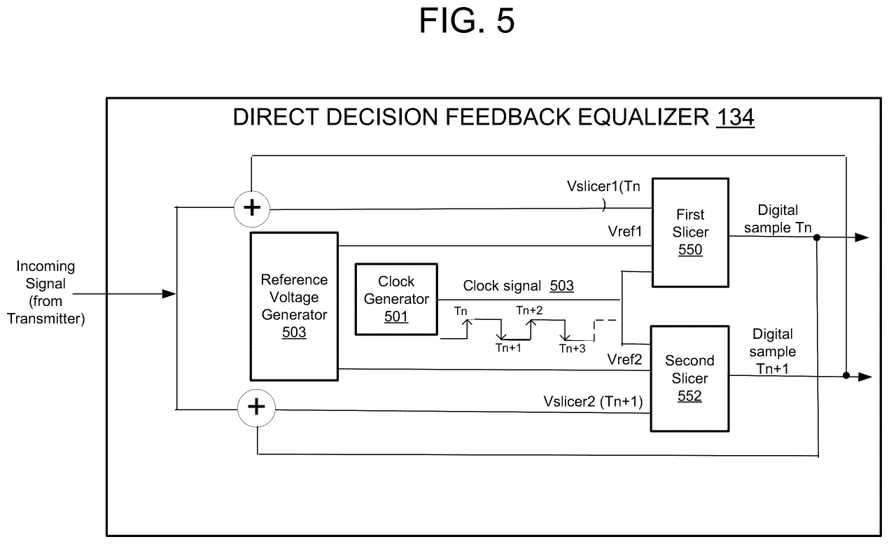

According to embodiments, the receiver 430 is a single-ended receiver including a direct DFE 134 which “directly” receives the transmitted data 101 as an input and performs non-linear equalization to generate a digital output 105 including decisions regarding the bit values (e.g., bit value “0” or “1”) corresponding to the incoming or transmitted signal, as described in greater detail with regard to FIG. 5.

FIG. 5 illustrates a direct decision feedback equalizer (DFE) 134, according to embodiments of the present disclosure. As shown in FIG. 5, the direct DFE 134 includes two data detector circuits (i.e., a first slicer 550 and a second slicer 552) that each generate digital outputs including digital decisions relating to a bit value of a corresponding sample of the incoming signal received from the transmitter. In an embodiment, a clock generator generates a clock signal 503 for use by the first slicer 550 and the second slicer 552 to collect a set of time-based samples of the incoming signal (e.g., a first sample, a second sample, a third sample, a fourth sample, a fifth sample, a sixth sample, and so on). For example, the first slicer 550 may take a first subset of samples (e.g., the first sample, the third sample, the fifth sample, etc.) corresponding to a first set of sample points based on the clock signal 503 (e.g., the first sample is taken at time Tn, the third sample at time Tn+2, and so on). Similarly, in this example, the second slicer 552 may take a second subset of samples (e.g., the second sample, the fourth sample, the sixth sample, and so on) corresponding to a second set of sample points based on the clock signal 503 (e.g., the second sample is taken at time Tn+1, the fourth sample is taken at time Tn+3, and so on).

As illustrated in FIG. 5, the direct DFE 134 includes a reference voltage generator 503 that generates a first reference voltage (Vref1) for use by the first slicer 550 and a second reference voltage (Vref2) for use by the second slicer 552. For example, the first slicer 550 compares a voltage level associated with a sample taken from the incoming signal (Vslicer1(Tn)) at a first time (e.g., Tn) to the first reference voltage (Vref1) to generate a digital sample (e.g., a bit value of “0” or “1” corresponding to the incoming signal at time Tn). Continuing this example, the second slicer 552 compares a voltage level associated with a sample taken from the incoming signal (Vslicer2(Tn+1)) at a second time (e.g., Tn+1) to the second reference voltage (Vref2) to generate a digital sample (e.g., a bit value of “0” or “1” corresponding to the incoming signal at time Tn+1).

According to embodiments, generating and supplying separate and different reference voltages to the respective slicers (i.e., the first slicer 550 and the second slicer 552) compensates for any offset between the first slicer 550 and the second slicer 552. Advantageously, the use of two different reference voltages (Vref1 supplied to the first slicer 550 and Vref2 supplied to the second slicer 552) to compensate for slicer offset eliminates the need to include dedicated offset compensation circuitry within the signal path. This results in an increase in the speed of the data processing of the direct DFE 134.

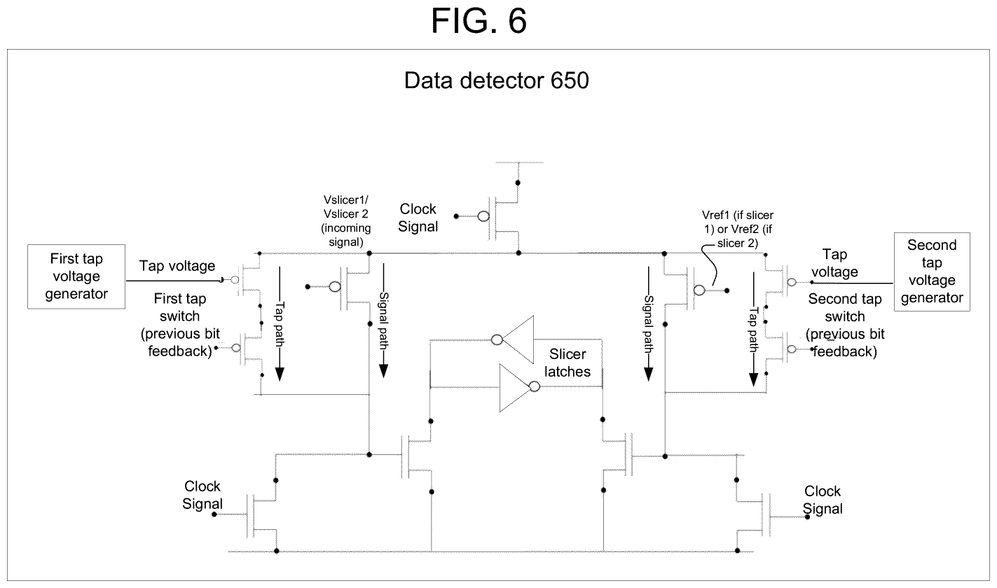

FIG. 6 illustrates an example one-tap data detector 650 (e.g., the first slicer 550 of FIG. 5 or the second slicer 552 of FIG. 5) of a direct DFE (e.g., direct DFE 134 of FIGS. 1A, 1B, 4 and 5), according to embodiments of the present disclosure. Although FIG. 6 illustrates elements of either a first slicer or a second slicer of direct DFE according to embodiments of the present disclosure, the following description refers to elements of the first slicer (e.g., the first slicer 550 of FIG. 5). As shown in FIG. 6, the data detector 650 includes a first tap voltage generator that generates a first tap voltage (e.g., a tap coefficient) that controls a first tap switch and a second tap voltage generator that generates a second tap voltage (e.g., a tap coefficient) that controls a second tap switch to control the bit feedback loop of the one-tap data detector 650. In an embodiment, a single tap voltage generator can be used to generate both the first tap voltage and the second tap voltage.

As illustrated, the one or more tap voltage generators are arranged in a circuit branch which is parallel to the corresponding signal path. Accordingly, the tap path and the signal path are parallel to one another, such that the tap switch and tap voltage generator are arranged in parallel to the signal path (i.e., outside of the signal path). As described above, the parallel-path tap voltage generation in a multi-tap configuration allows for the removal of capacitive circuits in the signal path. As a result of the tap coefficient branches being parallel to the signal path, the speed of the respective signal paths is increased.

As illustrated in FIG. 6, the data detector 650 receives a clock signal from a clock generator (e.g., clock generator 501 of FIG. 5) and a corresponding reference voltage (e.g., Vref1 for the first slicer 550 of FIG. 5 or Vref2 for the second slicer 552 of FIG. 5).

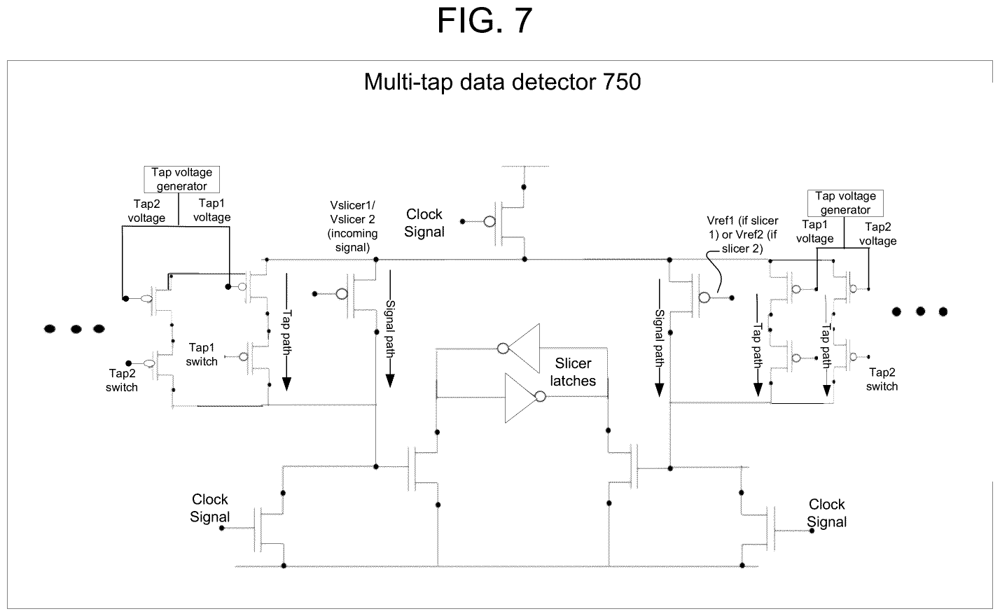

FIG. 7 illustrates an example multi-tap data detector 750 (e.g., the first slicer 550 of FIG. 5 or the second slicer 552 of FIG. 5) of a direct DFE (e.g., direct DFE 134 of FIGS. 1A, 1B, 4 and 5), according to embodiments of the present disclosure. As shown in FIG. 7, the multi-tap data detector 750 includes multiple taps (e.g., tap1 and tap2). According to embodiments, the multi-tap detector 750 may include any number of taps. In an embodiment, the multi-tap data detector 750 includes one or more tap voltage generators that generate tap voltages that controls the switches associated with the multiple taps. In an embodiment, a single tap voltage generator can be used to generate both the tap voltages for tap1, tap2, and so on.

As described above with reference to FIG. 6, the one or more tap voltage generators are arranged in one or more circuit branches which are parallel to the corresponding signal path. Accordingly, the tap path and the signal path are parallel to one another, such that the tap switches and tap voltage generator are arranged in parallel to the signal path (i.e., outside of the signal path). Advantageously, as compared to certain DFE architectures, the two data detectors 650 of the direct DFE 134 of the present disclosure do not include capacitive circuits in the signal path. As a result, the speed of the respective signal paths is increased by having standalone tap voltage generators that are parallel to the signal paths.

As illustrated in FIG. 6, the data detector 650 receives a clock signal from a clock generator (e.g., clock generator 501 of FIG. 5) and a corresponding reference voltage (e.g., Vref1 for the first slicer 550 of FIG. 5 or Vref2 for the second slicer 552 of FIG. 5).

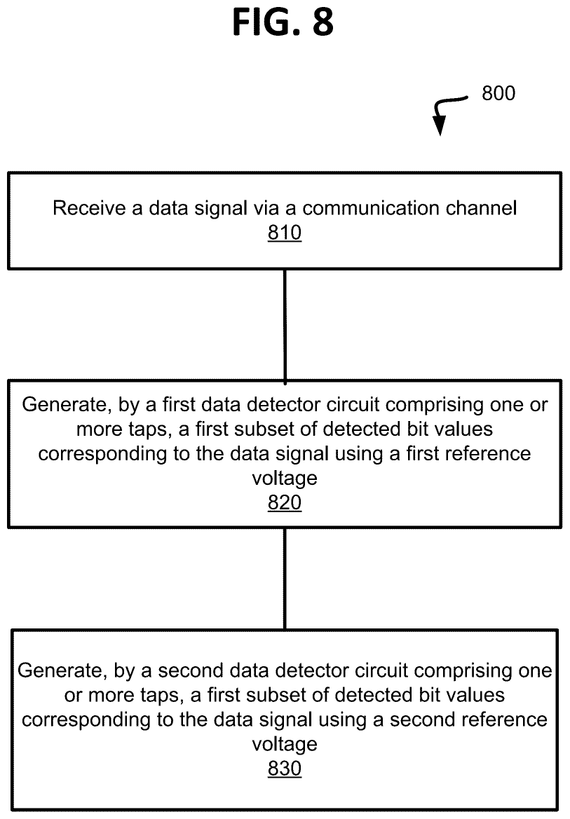

FIG. 8 is a flow diagram of an example method of generating a set of detected bit values corresponding to an incoming data signal received from transmitter via a communication channel. According to embodiments, the method 800 can be performed by a system or sub-system including circuitry (e.g., direct decision feedback equalizer 134 of FIGS. 1A, 1B, 4, and 5) of a single-ended receiver (e.g., a memory device of a memory sub-system) coupled to a transmitter (e.g., a memory sub-system controller of a memory sub-system) via a communication channel (e.g., communication channel 103 of FIG. 4). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 810, a signal is received. For example, the system (e.g., the direct DFE 134 of FIGS. 1A, 1B, 4 and 5) can receive a data signal via a communication channel. According to embodiments, the data signal can include data associated with one or more memory access operations to be executed with respect to a memory device (e.g., data to be programmed to at least a portion of a memory array a memory device). In an embodiment, the data signal can be transmitted by a memory sub-system controller (e.g., memory sub-system controller 115 of FIGS. 1A and 1B). In an embodiment, the data signal can be an analog signal that is communicated via the communication channel (e.g., a trace, a circuit board, a cable, etc.) and received “directly” (i.e., without pre-processing) by the direct DFE.

At operation 820, a first subset of values are generated. For example, a first data detector circuit having one or more taps (i.e., a first slicer) of the direct DFE can generate a first subset of detected bit values corresponding to the data signal using a first reference voltage. According to embodiments, the first data detector circuit can compare a voltage level associated with a sample of the data signal (e.g., a first sample taken at a first time Tn) to the first reference voltage level. In an embodiment, based on the comparison, the first data detector circuit generates a corresponding detected bit value (e.g., if the sampled voltage level is greater than the first reference voltage level then the detected bit value equals “1” and if the sampled voltage level is less than or equal to the first reference voltage level then the detected bit value equals “0”. According to embodiments, the first subset of detected bit values correspond to a first subset of samples taken by the first data detector (e.g., samples taken at time Tn, Tn+2, Tn+4, and so on).

At operation 830, a second subset of values are generated. For example, a second data detector circuit having one or more taps (i.e., a second slicer) of the direct DFE can generate a second subset of detected bit values corresponding to the data signal using a second reference voltage. According to embodiments, the second data detector circuit can compare a voltage level associated with a sample of the data signal (e.g., a sample taken at time Tn+1) to the second reference voltage level. In an embodiment, based on the comparison, the second data detector circuit generates a corresponding detected bit value (e.g., if the sampled voltage level is greater than the second reference voltage level then the detected bit value equals “1” and if the sampled voltage level is less than or equal to the second reference voltage level then the detected bit value equals “0”. According to embodiments, the second subset of detected bit values correspond to a second subset of samples taken by the first data detector (e.g., samples taken at time Tn+1, Tn+3, Tn+5, and so on).

According to embodiments, the first reference voltage and the second reference voltage are different from one another, as described in detail with reference to FIG. 5. Advantageously, the use of two different reference voltages (i.e., one for each slicer) results in the cancellation of offset between the two slicers, thereby enhancing the data rate of the direct DFE through the elimination of dedicated offset correction circuitry from the signal path.

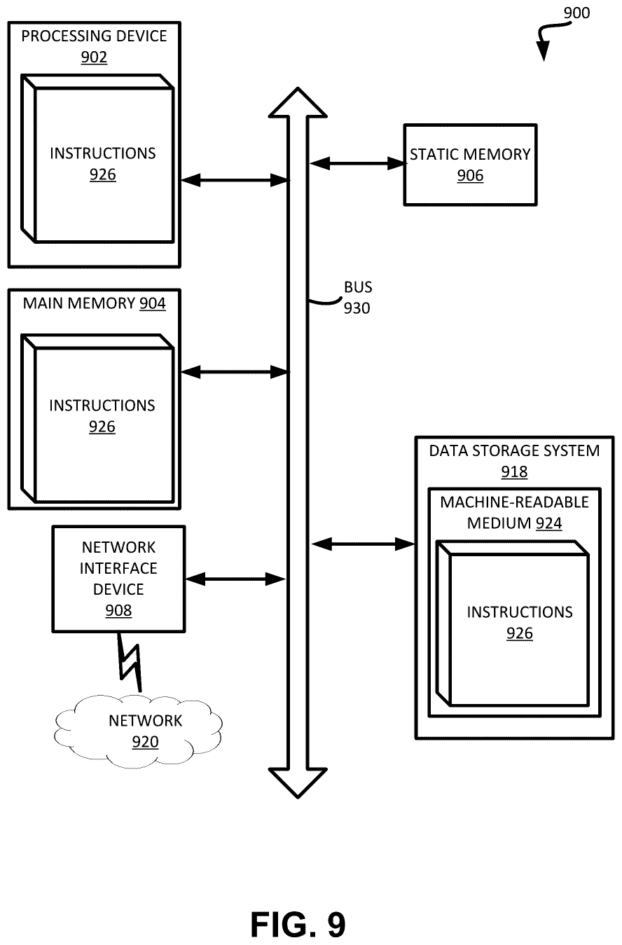

FIG. 9 illustrates an example machine of a computer system 900 within which a set of instructions, for causing the machine to perform any one or more of the methodologies discussed herein, can be executed. In some embodiments, the computer system 900 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to functionality of a direct DFE (as described above with reference to FIG. 1A, FIG. 1B, and FIGS. 4-8). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a memory cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM) or RDRAM, etc.), a static memory 906 (e.g., flash memory, static random access memory (SRAM), etc.), and a data storage system 918, which communicate with each other via a bus 930.

Processing device 902 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 can also be one or more special-purpose processing devices such as an application specific integrated circuit (ASIC), a field programmable gate array (FPGA), a digital signal processor (DSP), network processor, or the like. The processing device 902 is configured to execute instructions 926 for performing the operations and steps discussed herein. The computer system 900 can further include a network interface device 908 to communicate over the network 920.

The data storage system 918 can include a machine-readable storage medium 924 (also known as a computer-readable medium) on which is stored one or more sets of instructions 926 or software embodying any one or more of the methodologies or functions described herein. The instructions 926 can also reside, completely or at least partially, within the main memory 904 and/or within the processing device 902 during execution thereof by the computer system 900, the main memory 904 and the processing device 902 also constituting machine-readable storage media. The machine-readable storage medium 924, data storage system 918, and/or main memory 904 can correspond to the memory sub-system 110 of FIG. 1A.

In one embodiment, the instructions 926 include instructions to implement functionality corresponding to the processing of data signals by the direct DFE 134 of FIG. 1A, FIG. 1B, and FIGS. 4-8). While the machine-readable storage medium 924 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's page buffers and memories into other data similarly represented as physical quantities within the computer system memories or page buffers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory sub-system controller to transmit a data signal via a communication channel;
a receiver to receive the data signal from the memory sub-system controller via an interface, the receiver comprising a decision feedback equalizer (DFE) sub-system, the DFE sub-system comprising:
a first data detector circuit comprising a first tap circuit, wherein the first data detector circuit generates, using a first reference voltage, a first subset of detected values corresponding to the data signal; and
a second data detector circuit comprising a second tap circuit, wherein the second data detector circuit generates a second subset of detected bit values corresponding to the data signal using a second reference voltage.

2. The system of claim 1, wherein the DFE sub-system further comprises one or more reference voltage generation circuits to generate the first reference voltage and the second reference voltage.

3. The system of claim 1, wherein the first reference voltage is different from the second reference voltage.

4. The system of claim 1, wherein the first data detector circuit comprises a tap voltage generation circuit to generate a first tap voltage to control a first tap switch of the first tap circuit of and a second tap voltage to control a second tap switch of the first tap circuit of the first data detector circuit.

5. The system of claim 4, wherein the tap voltage generation circuit is arranged in parallel to a first path corresponding to the data signal.

6. The system of claim 1, wherein the receiver comprises a memory device comprising an array of memory cells.

7. The system of claim 6, wherein the data signal comprises data to be programmed to at least a portion of the array of memory cells.

8. A memory device comprising:
a memory array comprising a set of memory cells; and
a decision feedback equalizer (DFE) sub-system, the DFE sub-system comprising:
a first data detector circuit comprising a first tap circuit, wherein the first data detector circuit generates a first subset of detected bit values corresponding to a data signal using a first reference voltage; and
a second data detector circuit comprising a second tap circuit, wherein the second data detector circuit generates a second subset of detected bit values corresponding to the data signal using a second reference voltage.

9. The memory device of claim 8, wherein the DFE sub-system further comprises one or more reference voltage generation circuits to generate the first reference voltage and the second reference voltage.

10. The memory device of claim 8, wherein the first reference voltage is different from the second reference voltage.

11. The memory device of claim 8, wherein the first reference voltage and the second reference voltage cancel an offset between the first data detector circuit and the second data detector circuit.

12. The memory device of claim 8, wherein the first data detector circuit comprises a tap voltage generation circuit to generate a first tap voltage to control a first tap switch of the first tap circuit of and a second tap voltage to control a second tap switch of the first tap circuit of the first data detector circuit.

13. The memory device of claim 12, wherein the tap voltage generation circuit is arranged in parallel to a first path corresponding to the data signal.

14. A method comprising:
receiving a data signal via an interface coupled to a memory sub-system controller;
generating, by a first data detector circuit comprising a first tap circuit, a first subset of detected bit values corresponding to the data signal using a first reference voltage; and
generating, by a second data detector circuit comprising a second tap circuit, a first subset of detected bit values corresponding to the data signal using a second reference voltage.

15. The method of claim 14, further comprising generating, by one or more reference voltage generation circuits, the first reference voltage and the second reference voltage.

16. The method of claim 14, further comprising generating, by a tap voltage generation circuit, a first tap voltage to control a first tap switch of the first tap circuit and a second tap voltage to control a second tap switch of the second tap circuit the first data detector circuit.

17. The method of claim 14, wherein the first reference voltage is different from the second reference voltage.

18. The method of claim 14, wherein the first reference voltage and the second reference voltage cancel an offset between the first data detector circuit and the second data detector circuit.

19. The method of claim 14, generating, by a tap voltage generation circuit, a first tap voltage to control a first tap switch of the first tap circuit of and a second tap voltage to control a second tap switch of the first tap circuit of the first data detector circuit.

20. The method of claim 19, the tap voltage generation circuit is arranged in parallel to a first path corresponding to the data signal.
